(19) United States
(12) Patent Application Publication
(10) Pub. No.: US 2001/0049203 A1
(43) Pub. Date: Dec. 6, 2001

(54) Method of forming SiOC thin film having low dielectric constant

(75) Inventors: Hyeong J. Kim, Sungnam (KR); Yoon H. Kim, Seoul (KR); Young S. Lee, Sungnam (KR)

Correspondence Address: OSTROLENK FABER GERB & SOFFEN, 1180 AVENUE OF THE AMERICAS, NEW YORK, NY, 100368403

(73) Assignee: Jusung Engineering Co., Ltd.

(21) Appl. No.: 09/859,281

(22) Filed: May 17, 2001

(30) Foreign Application Priority Data
May 24, 2000 (KR) 27965/2000

(51) Int. Cl. H01L 21/31

(52) U.S. Cl. 438/778

(57) ABSTRACT

A method for forming a SiOC thin film includes the steps of: positioning a substrate in a reactive chamber; and supplying bis-trimethylsilylmethane (termed as ‘BTMSM’, hereinafter) as a source for silicon and carbon and an oxygen gas as a source for oxygen and performing a CVD process. Ssince CH2 is intensively bonded between the silicon atoms of the SiOC thin film, the SiOC thin film is formed having an excellent film quality. And accordingly, the wiring structure of the semiconductor device, which helps fabricate a semiconductor device with an excellent characteristic.

### BACKGROUND OF THE INVENTION

1. Field of the Invention

The present invention relates to a method for forming a thin film for use in a semiconductor device, and more particularly, to a method for forming an SiOC thin film with a low dielectric constant for use in a wiring structure of a semiconductor device.

2. Description of the Background Art

Admittedly, the recent remarkable development in an information and telecommunication sector, which is still making a rapid progress and expansion, is much owed to advancement of the semiconductor integrated device.

The semiconductor device which makes great contributions to the whole industries is being more highly integrated in order to improve its capability and yield.

Integration of a device is primarily attained by shortening the length of a gate of a transistor. Thus, integration serves as a factor to shorten a switching time of the transistor as the device is being more integrated.

However, in a device having an integration degree less than a sub micron, an increase in a resistance of a wiring caused due to the narrow line width and an RC signal delay occurring due to a capacitance attenuate the gain effect obtained by the reduction of the gate length. Besides, a problem arises that a cross talk and a power consumption increase.

Especially, as for the existing aluminum (Al)/silicon oxide film (SiO₂ film) wiring structure, that is, in case of using a structure that Al is used as a material for wiring and a silicon oxide film is used as an insulation material between wiring, a semiconductor device having a design rule of below 0.2μ, that is, for example, a 1 G DRAM device or a higher version thereof fabricated according to a 0.18 μm design rule reveals a degradation in a device characteristic due to the above mentioned problems. Especially, in case of a logic circuit device using more than 7-story metal wiring layers, the situation is more serious.

In considering that a design rule of a DRAM device and a ultra-highly integrated logic device advances to below 0.1 μm, a solution to the wiring problem would be the most urgent matter to open a new era of a semiconductor.

In efforts to solve the capability degradation of the device related to wiring, many researchers are conducting researches on an insulating material of a low dielectric constant and a wiring metal of a low resistance.

As a wiring metal, there have been many attempts to use Cu which has a lower nonresistance than aluminum, that has been conventionally used, and a less electromigration problem.

And as a new material for an insulation film, various organic substances and inorganic substances having less dielectric constant than that of the conventional SiO2 are now under research.

In this respect, Ken Monning of Sematech Co. released a very interesting statistics in 1994. According to him, the metal wiring structure of Al alloy/SiO₂ which is being currently used is changed to a structure of a Cu/barrier metal/SiO₂, about 50% of device characteristics are expected to be improved, while, in case that the SiO₂ is replaced with a material of a low dielectric constant, about 400% of improvement is expected.

At this stage that a swift switching to the structure of a Cu/low dielectric material is not easy, most researchers is first doing research on a metal wiring of a structure of an Al alloy/ low dielectric constant material. And, it is highly expected that a development of a new low dielectric constant thin film and accomplishment of its process would much affect every semiconductor device.

Roughly, there are two tendencies of researches on the low dielectric constant thin film according to a material: one is an organic material such as a polymer, which has a low dielectric constant of about 50% compared to that of the existing SiO₂ film but has a bad compatibility to a follow-up process due to problems of its inferiority of thermal stability, a resistance to oxygen plasma and a mechanical strength, and the other is a low dielectric constant thin film of an inorganic substance, having a form that the existing SiO₂ film is partially deformed, which can be used without much changing the existing equipment and processes and has a good compatibility to a follow-up process, but with problem that its dielectric constant is not much reduced compared to that of the SiO2 film and it is weak to moisture of the atmosphere.

Up to now, the research on the low dielectric constant material has been focussed solely on the organic substance or solely on the inorganic substance. Recently, however, researchers turn to complementing the merits and demerits of the organic or the inorganic substances.

That is, as a hybrid-type material, that draws much attention as a material for a next-generation low dielectric constant insulation film, there is a SiOC obtained by containing a large amount of carbon into the existing SiO₂ film. The reason why SiOC has a low dielectric constant is known a low polarizability of a Si—C bond and a void formed in a film.

The SiOC thin film can be formed by a chemical vapor deposition (CVD). In this case, methylsilane, dimethylsilane, tri-methylsilane or tetra-methylsilane and so forth is used as a source.

The reasons why the SiOC thin film has a low dielectric constant can be briefed by the following descriptions.

That is, first, the void having a size of nano meter formed as carbon contained as CHₙ in a thin film dangles a part of SiO₂ having a mesh structure invites the low dielectric constant.

Secondly, it is believed that the Si—CH₃ bonding has a less ion polarizability compared to the Si—O bonding, a mechanism of which, however, has not been identified.

Referring to the cause of the low dielectric constant, it is critical to include more carbon in the thin film to obtain a low dielectric constant thin film. In this respect, however, since the thermal and mechanical characteristics is degraded as the amount of carbon increases, it is necessary to establish a deposition process in consideration of such characteristics.

### SUMMARY OF THE INVENTION

Therefore, an object of the present invention is to provide a method for forming a SiOC thin film having a low dielectric constant of which characteristics would not be degraded even though a large amount of carbon is contained therein.

Another object of the present invention is to provide a method for forming a SiOC thin film having a low dielectric constant by selecting a source which can be easily handled.

To achieve these and other advantages and in accordance with the purpose of the present invention, as embodied and broadly described herein, there is provided a method for forming a SiOC thin film including the steps of: positioning a substrate in a reactive chamber; and supplying bis-trimethylsilylmethane (termed as ‘BTMSM’, hereinafter) as a source for silicon and carbon and an oxygen gas as a source for oxygen and performing a CVD process.

In the method for forming a SiOC thin film in accordance with the present invention, it is preferred that the substrate is maintained at the temperature of 25˜400° C. during the CVD process.

In the method for forming a SiOC thin film in accordance with the present invention, it is preferred that BTMSM is supplied into the reactive chamber by argon and helium carrier gas during the CVD process.

In the method for forming a SiOC thin film in accordance with the present invention, more preferably, the plasma enhanced chemical vapor deposition (PECVD) is performed. In such a case, an electrode is installed in the reactive chamber to generate a capacitively coupled plasma and a plasma power of 50˜500 W is applied to the electrode during the PECVD process.

Preferably, a step for rotating the substrate at a constant rate may be included during the PECVD process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a drawing illustrating a structure of a BTMSM for use in a method for forming a SiOC thin film having a low dielectric constant; and

FIG. 2 is a schematic sectional view of a thin film forming apparatus for use in a preferred embodiment of the present invention.

### DETAILED DESCRIPTION OF THE PREFERRED EMBODIMENTS

Reference will now be made in detail to the preferred embodiments of the present invention, examples of which are illustrated in the accompanying drawings.

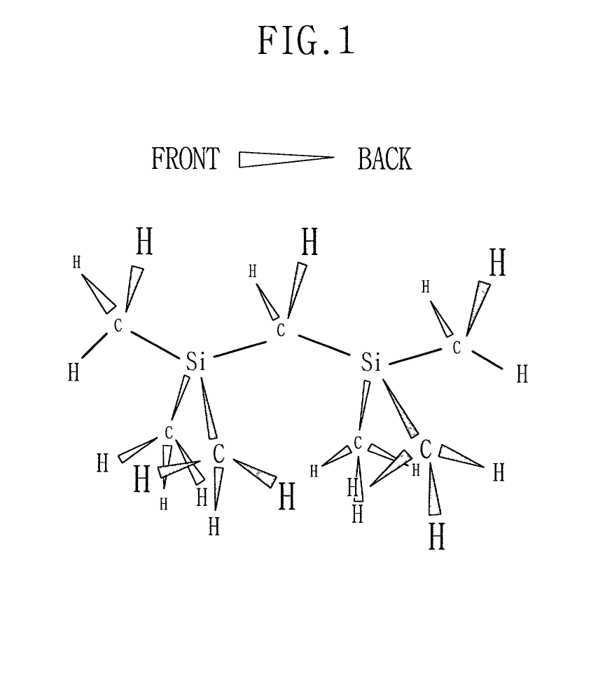

FIG. 1 is a drawing illustrating a structure of a BTMSM for use in a method for forming a SiOC thin film having a low dielectric constant.

As shown in FIG. 1, a molecular formula is Si₂(CH₂)(C₃H₉)₂, from which it is noted that carbon, strictly speaking, CH₂, exists between two silicon atoms, unlike methylsilane, dimethylsilane, tri-methylsilane and tetra-methylsilane, sources for the conventional SiOC thin film deposition.

Since carbon is commonly bonded to the silicon atoms of both sides, it has a strong bonding power compared to a different carbon component (CH₃). This shows that silicon and carbon has been stably bonded in BTMSM, and compared to other sources, more carbon amount is contained in the SiOC thin film under the same process condition. And, there is much likelihood that the SiOC thin film characteristics can be stably maintained, even though a follow-up semiconductor device fabrication process is performed after the thin film deposition.

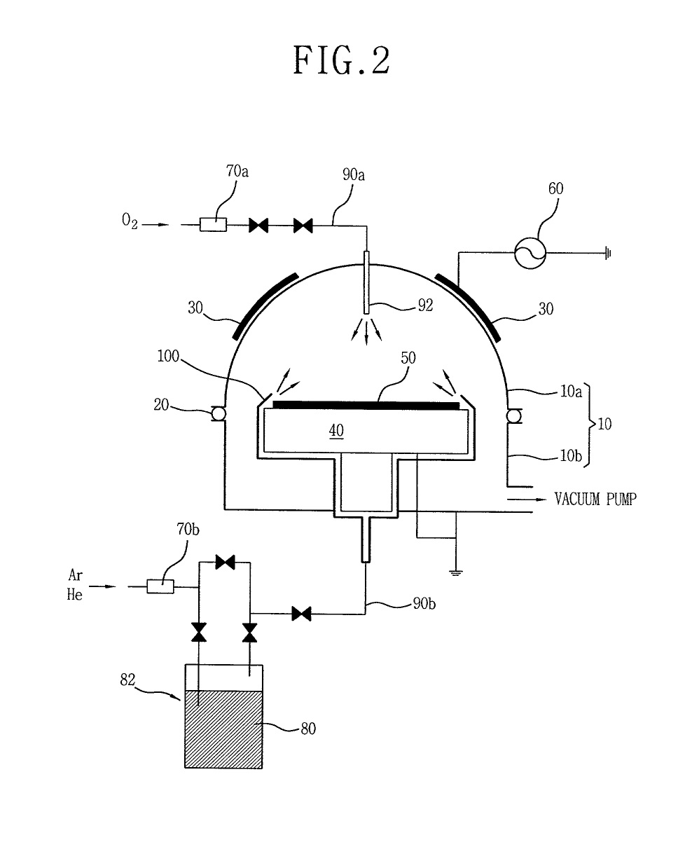

Another strong point of BTMSM lies in that it is easily handled. Namely, BTMSM is a substance having the boiling point of 132° C., the melting point of −71° C. Thus, at a room temperature, it is in a liquid phase, incombustible and nontoxic, and has a comparatively less air-sensitivity, so that it is easily handled FIG. 2 is a schematic sectional view of a thin film forming apparatus for use in a preferred embodiment of the present invention.

With reference to FIG. 2, a reactive chamber 10 consisting of an upper container 10a and a lower container 10b and an O-ring 20 positioned therebetween provides a closed reactive space for a semiconductor substrate 50 mounted at a suscepter 40.

The upper reactive chamber 10a is formed in a dome shape, and as disclosed in the Korean Patent Application No. 1999-61858, a plasma electrode 30 having an opening is installed to surround the reactive chamber 10a.

An RF power generator 60 for applying a radio frequency (RF) power is connected to the plasma electrode 30.

A heater (not shown) for controlling a temperature of the substrate 50 is installed both at the outer wall of the chamber 10 and inside the suscepter 40.

A first mass flow controller 70a, a first feed pipe 90a and an injector 92 for supplying O₂, an oxygen gas, into the reactive chamber 10 in forming an SiOC thin film are connected in line.

Valves for opening and closing flowing of O₂ are installed at parts of the first feed pipe 90a.

BTMSM 80, the source for forming the SiOC thin film, is stored in a thermostatic bubbler 82 which constantly maintains a vapor pressure.

A second mass flow controller 70b, a second feed pipe 90b and a gas focus ring 100 for supplying BTMSM 80 into the reactive chamber are arranged in line.

The thermostatic bubbler 82 is positioned between the second mass flow controller 70b and the second feed pipe 90b, so that only Ar and He gas are supplied or BTMSM using Ar and He gas as a carrier gas is supplied into the reactive chamber 10 according a selective opening and closing of the valves.

The lower portion of the reactive chamber is connected to a vacuum pump such as a booster pump, a rotary pump or a turbo molecular pump, so that the inner side of the reactive chamber can be maintained at a low pressure.

A method for forming an SiOC thin film by using the above-described thin film forming apparatus will now be described.

In a state that the substrate 50 on the suscepter 40 is maintained at a temperature of 300° C., BTMSM and the carrier gas such as Ar and He are sprayed in the vicinity of the substrate 50 through the gas focus ring 100. The gas focus ring is used as being disclosed in the Korean Patent Application No. 1999-48526 to evenly feed BTMSM source from the marginal portion of the substrate 50 to the central portion.

At the same time, O₂, the oxygen reactive gas, is sprayed to the upper portion of the substrate 50 through the injector 92.

The flow amount of the Ar and He carrier gas is controlled within 50˜500 sccm, and that of O2 is controlled within 50˜1000 sccm.

At this time, the internal pressure of the reactive chamber is controlled 1˜scores of torr.

To have an effective decomposition of BTMSM and facilitate the reaction, an RF power of 13.56 MHz and 300 W is applied to the plasma electrode 30. When the substrate is rotated during deposition, a thin film with an even thickness can be formed.

In the preferred embodiment of the present invention, O₂ gas is used as the oxygen reactive gas. Besides, however, ozone (O₃), N₂O gas or H₂O₂ may be also used.

As so far described, the method for forming an SiOC thin film by using BTMSM source has the advantage that since CH2 is intensively bonded between the silicon atoms of the SiOC thin film, the SiOC thin film is formed having an excellent film quality. And accordingly, the wiring structure of the semiconductor device, which helps fabricate a semiconductor device with an excellent characteristic.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. A method for forming a SiOC thin film comprising:
positioning a substrate in a reactive chamber; and
supplying bis-trimethylsilylmethane as a source for silicon and carbon and an oxygen gas as a source for oxygen and performing a CVD process.

2. The method of claim 1, wherein the substrate is maintained at the temperature of 25˜400° C. during the CVD process.

3. The method of claim 1, wherein BTMSM is supplied into the reactive chamber by argon and helium carrier gas during the CVD process.

4. The method of claim 1, wherein the CVD process refers to a plasma enhanced chemical vapor deposition

5. The method of claim 4, wherein an electrode is installed in the reactive chamber to generate a capacitively coupled plasma and a plasma power of 50˜500 W is applied to the electrode during the PECVD process.

6. The method of claim 4, further comprising a step for rotating the substrate at a constant rate during the PECVD process.
